(19) United States
(12) Patent Application Publication
(10) Pub. No.: US 2026/0333986 A1
(43) Pub. Date: Oct. 22, 2026

(54) TRANSPARENT DISPLAY

(71) Applicant: AUO Corporation, Hsinchu City (TW)

(72) Inventors: Ching-Liang HUANG, Hsinchu City (TW); Jia-Hong YE, Hsinchu City (TW); Shu-Hao HUANG, Hsinchu City (TW); Sung-Yu SU, Hsinchu City (TW)

(21) Appl. No.: 19/403,381

(22) Filed: Nov. 28, 2025

(30) Foreign Application Priority Data
Apr. 17, 2025 (TW) 114114633

(51) Int. Cl. H10H 29/855; H10H 29/49

(52) U.S. Cl. CPC H10H 29/8552; H10H 29/49

(57) ABSTRACT

A transparent display includes a light-transmitting composite substrate, an inner insulating layer, an outer insulating layer, an opaque layer, an inner wiring layer, a plurality of electrode layers and a plurality of light-emitting components disposed on the electrode layers. The inner insulating layer is disposed on the light-transmitting composite substrate. The outer insulating layer is disposed on the inner insulating layer. The opaque layer defines transparent areas on the outer insulating layer. The electrode layers disposed on the outer insulating layer respectively have side edges. Each side edge is adjacent to one of the transparent areas. The opaque layer protrudes from each side edge by a protruding length. There is a perpendicular distance formed between the electrode layers and the inner wiring layer. The ratio of the protrusion length to the perpendicular distance is greater than or equal to 2.

### CROSS-REFERENCE TO RELATED APPLICATION

This application claims priority to Taiwan Application Serial Number 114114633, filed Apr. 17, 2025, which is herein incorporated by reference in its entirety.

### BACKGROUND

### Technical Field

The present disclosure relates to a display. More particularly, the present disclosure relates to a transparent display.

### Description of Related Art

A conventional transparent display usually has a plurality of metal wiring layers and Light Emitting Diodes (LEDs), and transmits electric currents to the LEDs by using the metal wiring layers, so that the LEDs can emit light. However, these metal wiring layers each have noticeably high optical reflectivity and thus can reflect the light from LEDs, thereby easily causing light leakage (or light bleeding) and resulting in low image quality.

### SUMMARY

The disclosure according to at least one embodiment provides a transparent display, so as to help to reduce or prevent light leakage (or light bleeding).

At least one embodiment according to the present disclosure provides a transparent display including a light-transmitting composite substrate, an inner insulating layer, an outer insulating layer, an opaque layer, a first inner wiring layer, a plurality of electrode layers, and a plurality of light-emitting components. The inner insulating layer is disposed on the light-transmitting composite substrate. The outer insulating layer is disposed on the inner insulating layer and has a plane. The opaque layer is disposed on the abovementioned plane and includes a plurality of first opaque bars extending in a first direction and a plurality of second opaque bars extending in a second direction. The opaque layer defines a plurality of transparent areas on the plane of the outer insulating layer, in which the first opaque bars and the second opaque bars are located around the transparent areas. The first inner wiring layer is disposed on the inner insulating layer and covered by the outer insulating layer. The electrode layers are disposed on the plane of the outer insulating layer and have a plurality of side edges respectively. Each of the side edges is adjacent to one of the transparent areas, while the opaque layer covers each of the side edges and protrudes from each of the side edges by a protruding length in the first direction. There is a perpendicular distance formed between the electrode layers and the first inner wiring layer, and a ratio of the protruding length to the perpendicular distance is greater than or equal to 2. The light-emitting components are disposed on the electrode layers.

Another embodiment according to the present disclosure provides a transparent display including a light-transmitting composite substrate, an inner insulating layer, an outer insulating layer, an opaque layer, a plurality of electrode layers, a first inner wiring layer, and a plurality of light-emitting components. The inner insulating layer is disposed on the light-transmitting composite substrate. The outer insulating layer is disposed on the inner insulating layer and has a plane. The opaque layer is disposed on the abovementioned plane and includes a plurality of first opaque bars extending in a first direction and a plurality of second opaque bars extending in a second direction. The opaque layer defines a plurality of transparent areas on the plane of the outer insulating layer, and the first opaque bars and the second opaque bars are located around the transparent areas. The electrode layers are disposed on the plane of the outer insulating layer and have a plurality of side edges respectively, where each of the side edges is adjacent one of the transparent areas, and the opaque layer covers each of the side edges. The electrode layers include a plurality of cathodes and a plurality of anodes. The cathodes have a plurality of slits extending in the second direction while at least a portion of the opaque layer is located in the slits. Each of the anodes is disposed opposite to one of the cathodes, where each of the light-emitting components is disposed on one of the anodes and one of the cathodes. The first inner wiring layer is disposed on the inner insulating layer and covered by the outer insulating layer. The light-emitting components are disposed on the electrode layers.

Another embodiment according to the present disclosure provides a transparent display including a light-transmitting composite substrate, an inner insulating layer, an outer insulating layer, an opaque layer, a plurality of electrode layers, a first inner wiring layer, and a plurality of light-emitting components. The inner insulating layer is disposed on the light-transmitting composite substrate. The outer insulating layer is disposed on the inner insulating layer and has a plane. The opaque layer is disposed the abovementioned plane and includes a plurality of first opaque bars in a first direction and a plurality of second opaque bars extending in a second direction. The opaque layer defines a plurality of transparent areas on the plane of the outer insulating layer, and the first opaque bars and the second opaque bars are located around the transparent areas. The electrode layers are disposed the plane of the outer insulating layer and have a plurality of side edges respectively, where each of the side edges is adjacent one of the transparent areas, and the opaque layer covers each of the side edges. At least one of the electrode layers includes a blackened conductive layer and a metal layer. The blackened conductive layer is disposed on the plane of the outer insulating layer, while the metal layer is disposed on the blackened conductive layer. The first inner wiring layer is disposed on the inner insulating layer and covered by the outer insulating layer. The light-emitting components are disposed on the electrode layers.

As a result, in the transparent display, at least one of the opaque layer and the blackened conductive layer can absorb the reflected light in the outer insulating layer, so as to reduce or prevent light leakage, thereby improving the image quality of the transparent display.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1A is a top view of a transparent display according to at least one embodiment of the present disclosure.

FIG. 1B is an enlarged view of a portion of FIG. 1A.

FIG. 2A is a cross-sectional view of FIG. 1B along a line 2-2.

FIG. 2B is an enlarged view of a portion of FIG. 2A.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

In the following description, in order to clearly present the technical features of the present disclosure, the dimensions (such as length, width, thickness, and depth) of elements (such as layers, films, substrates, and areas) in the drawings will be enlarged in unusual proportions, and the quantity of some elements will be reduced. Accordingly, the description and explanation of the following embodiments are not limited to the quantity, sizes and shapes of the elements presented in the drawings, but should cover the sizes, shapes, and deviations of the two due to actual manufacturing processes and/or tolerances. For example, the flat surface shown in the drawings may have rough and/or non-linear characteristics, and the acute angle shown in the drawings may be round. Therefore, the elements presented in the drawings in this case which are mainly for illustration are intended neither to accurately depict the actual shape of the elements nor to limit the scope of patent applications in this case.

It should be understood that, although the terms first, second, third etc. may be used herein to describe various elements, components, regions, layers, portions and/or sections, these elements, components, regions, layers, portions and/or sections should not be limited by these terms. These terms are only used to distinguish one element, component, region, layer, portion or section from another region, layer, or section. Thus, a first element, component, region, layer, portion, or section discussed below could be termed a second element, component, region, layer, portion, or section without departing from the teachings of the present disclosure.

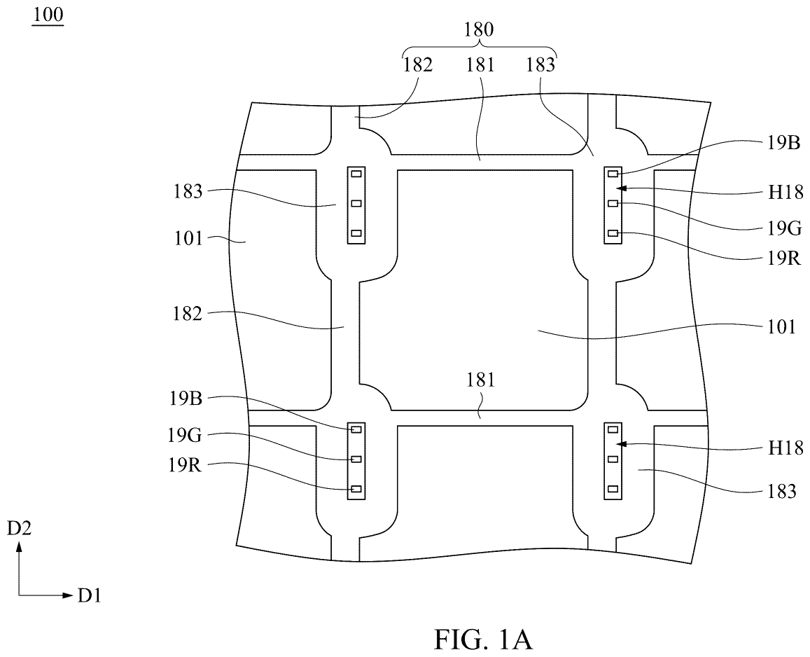

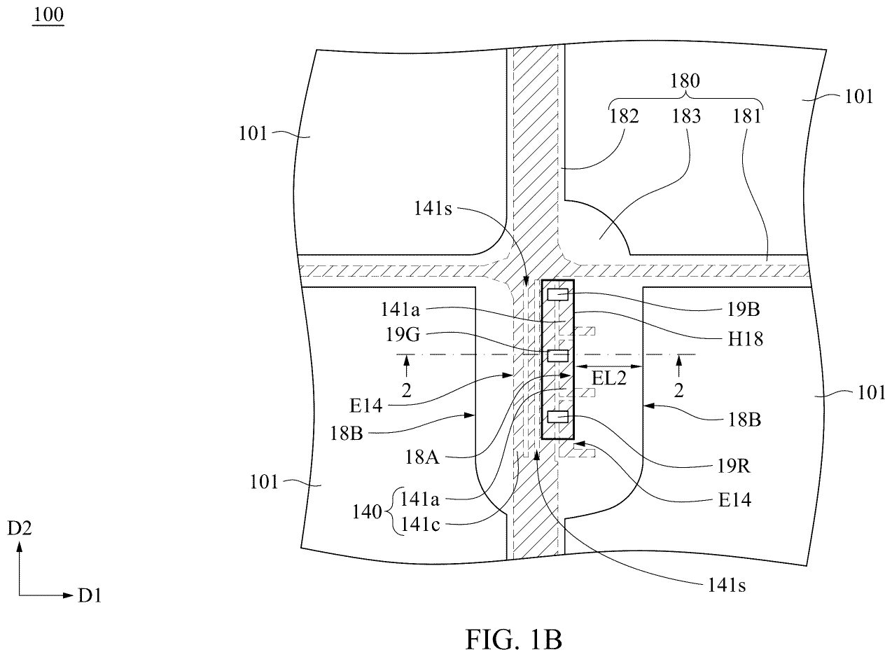

FIG. 1A is a top view of a transparent display according to at least one embodiment of the present disclosure. Referring to FIG. 1A, a transparent display 100 includes an opaque layer 180 and a plurality of light-emitting components 19R, 19G, and 19B, in which the opaque layer 180 has a plurality of openings H18, while the light-emitting components 19R, 19G, and 19B are located in the openings H18 respectively. Taking FIG. 1A for example, there may be three light-emitting components, i.e., light-emitting components 19R, 19G, and 19B, disposed in each of the openings H18, where the light-emitting components 19R, 19G, and 19B can emit various color light. For example, the light-emitting components 19R can emit red light; the light-emitting components 19G can emit green light; and the light-emitting components 19B can emit blue light.

These light-emitting components 19R, 19G, and 19B may be Light Emitting Diodes (LEDs), such as micro-LEDs, (μLEDs) or mini-LEDs. The light-emitting components 19R, 19G, and 19B can emit various color light, for example, red light, green light, and blue light, so that the light-emitting components 19R, 19G, and 19B can be red LED, green LED, and blue LED respectively. That is, the light-emitting components 19R, 19G, and 19B include three types of LEDs. The transparent display 100 can display color images via the various color light (e.g., red light, green light, and blue light) from the light-emitting components 19R, 19G, and 19B.

In addition, in another embodiment, the transparent display 100 can include an additional type of LED, such as yellow LED. In other words, the light-emitting components may include four types of LEDs: red LED, green LED, blue LED, and yellow LED, so as to improve the color quality of the image. Four light-emitting components, e.g., light-emitting components 19R, 19G, 19B, and yellow LED, may be disposed in one opening H18.

It is necessary to note that the light-emitting components 19R, 19G, and 19B may be replaced by light-emitting components of a single type and thus can emit the light with one kind of color, such as whit light, so that the transparent display 100 can display images composed of a single color. For example, in another embodiment, the light-emitting components 19R, 19G, and 19B can be replaced by white LEDs, so that the light-emitting components 19R, 19G, and 19B can emit white light, thereby causing the transparent display 100 to display white images. Hence, the light-emitting components 19R, 19G, and 19B are not limited to red, green, and blue LEDs.

The opaque layer 180 includes a plurality of first opaque bars 181 and a plurality of second opaque bars 182. The first opaque bars 181 extend in the first direction D1, while the second opaque bars 182 extend in the second direction D2, where the first direction D1 is different from the second direction D2. For example, the first direction D1 may be perpendicular to the second direction D2. Since the first opaque bars 181 extend in the first direction D1, and the second opaque bars 182 extend in the second direction D2, these first opaque bars 181 and these second opaque bars 182 are arranged in a mesh. That is, the opaque layer 180 can be in the shape of a mesh, as shown in FIG. 1A.

The transparent display 100 has a plurality of transparent areas 101, where at least one of the transparent areas 101 is surrounded by the opaque layer 180. In the present embodiment, the opaque layer 180 surrounds multiple transparent areas 101, where the first opaque bars 181 and the second opaque bars 182 are located around the transparent areas 101. Taking FIG. 1A for example, two adjacent first opaque bars 181 and two adjacent second opaque bars 182 surround one of the transparent areas 101.

The opaque layer 180 may include a plurality of opaque blocks 183, in which the opaque blocks 183 are connected to the first opaque bars 181 and the second opaque bars 182. Taking FIG. 1A for example, one opaque block 183 connected to two adjacent first opaque bars 181 and two adjacent second opaque bars 182 is located between the two first opaque bars 181, and between the two second opaque bars 182. Furthermore, four adjacent opaque blocks 183 are located around one transparent area 101, so that the four adjacent opaque blocks 183, two adjacent first opaque bars 181, and two adjacent second opaque bars 182 surround one transparent area 101, as shown in FIG. 1A. In addition, the opaque blocks 183 have the openings H18 respectively.

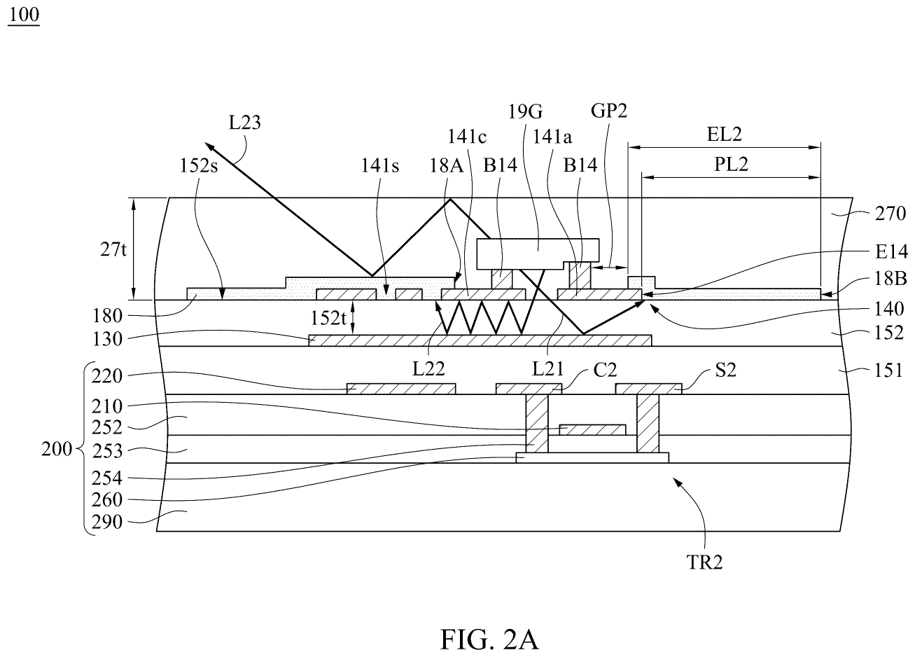

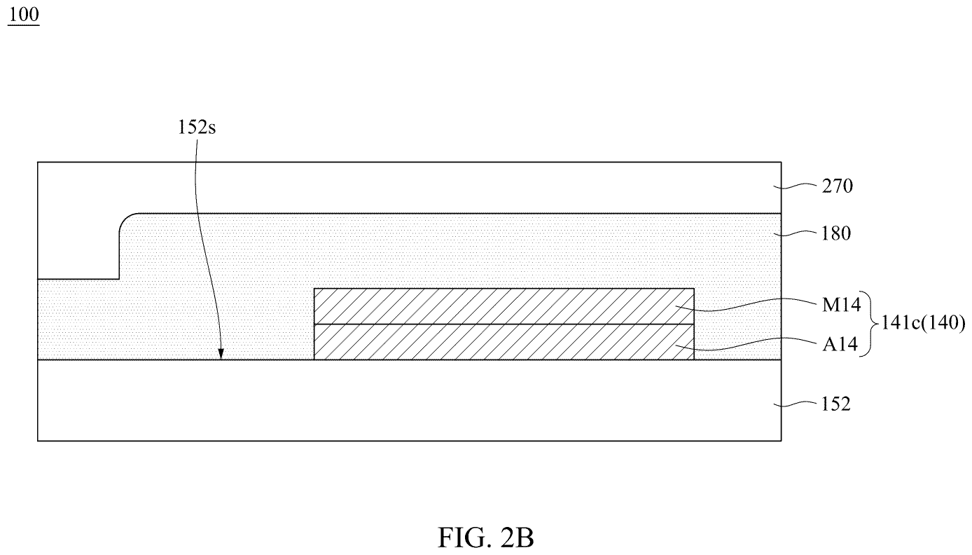

FIG. 1B is an enlarged view of a portion of FIG. 1A, while FIG. 2A is a cross-sectional view of FIG. 1B along a line 2-2. FIG. 2A is also a cross-sectional view of FIG. 1B in the first direction D1. Referring to FIG. 1B and FIG. 2A, the transparent display 100 further includes a light-transmitting composite substrate 200, an inner insulating layer 151, an outer insulating layer 152, a first inner wiring layer 130, and an outer wiring layer 140. The inner insulating layer 151 is disposed on the light-transmitting composite substrate 200, while the outer insulating layer 152 and the first inner wiring layer 130 are disposed on the inner insulating layer 151. The outer insulating layer 152 has a plane 152s, in which the outer wiring layer 140 and the opaque layer 180 are disposed on the plane 152s, and the first inner wiring layer 130 is covered by the outer insulating layer 152. In addition, the opaque layer 180 defines the transparent areas 101 on the plane 152s.

The light-emitting components 19R, 19G, and 19B are disposed on the outer wiring layer 140. Specifically, the outer wiring layer 140 includes a plurality of electrode layers 141c and 141a, in which the light-emitting components 19R, 19G, and 19B are disposed on the electrode layers 141a and 141c and electrically connected to the electrode layers 141a and 141c, so that the light-emitting components 19R, 19G, and 19B can receive electric currents from the electrode layers 141a and 141c and thus emit light.

The electrode layers 141a may be anodes, while the electrode layers 141c may be cathodes. That is, the electrode layers 141a and 141c of the outer wiring layer 140 include a plurality of anodes (i.e., electrode layers 141a) and a plurality of cathodes (i.e., electrode layers 141c). Each of the electrode layers 141a (i.e., anode) is disposed opposite to one of the electrode layers 141c (i.e., cathode), in which each of the light-emitting components 19R, 19G, and 19B is disposed on one of the electrode layers 141a (i.e., anode) and one of the electrode layers 141c (i.e., cathode).

The light-emitting components 19R, 19G, and 19B are electrically connected to the electrode layers 141a and 141c in the same manner. The electrical connection between the light-emitting component 19G and both of the electrode layers 141a and 141c is illustrated in FIG. 2A, for example. The light-emitting components 19R and 19B are electrically connected to the electrode layers 141a and 141c in the same way as the cross-sectional structure shown in shown in FIG. 2A. It is necessary to note that the first inner wiring layer 130 and the outer wiring layer 140 can be electrically connected to each other via multiple contact windows (not shown), in which the contact window is a conductive pillar passing through the outer insulating layer 152 and connected to the first inner wiring layer 130 and the outer wiring layer 140.

The transparent display 100 includes a plurality of conductive members B14, where the conductive members B14 are disposed on the electrode layers 141c and 141a respectively, and can directly touch and be connected to the electrode layers 141c and 141a, so that the conductive members B14 are electrically connected to the electrode layers 141c and 141a. The light-emitting components 19R, 19G, and 19B are disposed on the conductive members B14. That is, the conductive members B14 are located between the outer wiring layer 140 and any one of the light-emitting components 19R, 19G, and 19B.

The light-emitting components 19R, 19G, and 19B are electrically connected to the conductive members B14. Hence, the light-emitting components 19R, 19G, and 19B can be electrically connected to the electrode layers 141c and 141a via the conductive members B14, so that the electrode layers 141c and 141a can transmit electric currents to the light-emitting components 19R, 19G, and 19B, and thus the light-emitting components 19R, 19G, and 19B can emit light. In addition, the conductive members B14 may be bumps and made of solder or indium.

The electrode layers 141a and 141c disposed on the plane 152s have a plurality of side edges E14 respectively, in which each of the side edges E14 is adjacent to one of the transparent areas 101 and may extend in the second direction D2. The opaque layer 180 covers the outer wiring layer 140 and further covers these electrode layers 141a and 141c. The opaque blocks 183 of the opaque layer 180 further covers each side edge E14 and protrudes from each of the side edges E14 by a protruding length PL2 in the first direction D1, where the protruding length PL2 extends in the first direction D1.

There is a perpendicular distance 152t formed between the first inner wiring layer 130 and both of the electrode layers 141a and 141c (i.e., outer wiring layer 140) and the perpendicular distance 152t, and a ratio of the protruding length PL2 to the perpendicular distance 152t is greater than or equal to 2. When the light-emitting component (e.g., light-emitting components 19G) emits the light L21 (e.g., green light) at a relatively large incident angle, the first inner wiring layer 130 located directly below the light-emitting components 19G will reflect the light L21 at a relatively large reflective angle.

Since the ratio of the protruding length PL2 to the perpendicular distance 152t is greater than or equal to 2, the light L21 reflecting off the first inner wiring layer 130 easily enters the portion of the opaque layer 180 protruding from the side edge E14 and thus is easy to be absorbed by the opaque layer 180. As a result, the light L21 undergoing the reflection inside the outer insulating layer 152 is easy to be absorbed by the opaque layer 180 and thus is difficult to exit the outer insulating layer 152, thereby reducing or preventing light leakage, and improving the image quality of the transparent display 100.

The transparent display 100 may further include a molding layer 270. The molding layer 270 is disposed on the plane 152s of the outer insulating layer 152 and covers the light-emitting components 19R, 19G, and 19B, where the molding layer 270 has a thickness 27t. The molding layer 270 is transparent to visible light. That is, the molding layer 270 transmits visible light, so that the light emitted from the light-emitting components 19R, 19G, and 19B can pass through the molding layer 270 and then exit the transparent display 100.

The opaque layer 180 has a plurality of inner edges 18A and outer edges 18B, where the inner edges 18A are located on the electrode layers 141a and 141c, and the outer edges 18B are adjacent to the transparent areas 101. One of the opaque blocks 183 of the opaque layer 180 may have two inner edges 18A and two outer edges 18B. The inner edges 18A and the outer edges 18B may extend in the second direction D2. The inner edge 18A can be a sidewall of one of the openings H18 which extends in the second direction D2, while the inner edge 18A faces the light-emitting components 19R, 19G, and 19B. In addition, in a single opaque block 183, a gap GP2 formed between the inner edge 18A and the conductive member B14 which are adjacent to each other can range between 3 μm and 20 μm.

In the inner edge 18A and the outer edge 18B which are adjacent to each other, that is in a single opaque block 183, the opaque layer 180 (i.e., opaque block 183) has an extension length EL2 extending in the first direction D1 and from the inner edge 18A to the outer edges 18B, in which a ratio of the extension length EL2 to the thickness 27t of the molding layer 270 is greater than or equal to 5. The refractive index of the molding layer 270 may range between 1.3 and 1.7, such as 1.4, while the Optical Density (OD) of the opaque layer 180 can be greater than or equal to 1, such as between 4 and 4.2, in which the OD is the same as or equivalent to absorbance. In addition, the thickness of the opaque layer 180 may be about 1 μm, while the average reflectivity of the opaque layer 180 may be about 7.4%.

Since the refractive index of the molding layer 270 may range between 1.3 and 1.7, a critical angle formed between the molding layer 270 and the air can range between 36 degree and 50 degree. When the refractive index of the molding layer 270 is 1.4, the critical angle between the molding layer 270 and the air is about 45 degree. When the light-emitting component (e.g., light-emitting component 19G) emits the light L23 upwards, since the ratio of the extension length EL2 to the thickness 27t of the molding layer 270 is greater than or equal to 5, the light L23 reflecting off the interface between the molding layer 270 and the air mostly enters the opaque layer 180 and thus is absorbed by the opaque layer 180. Accordingly, the emission of the light L23 which undergoes total internal reflection from the molding layer 270 can be reduced, so as to reduce or prevent light leakage, thereby improving the image quality.

These electrode layers 141c (i.e., cathodes) have a plurality of slits 141s extending in the second direction D2, in which the slits 141s do not overlap the light-emitting components 19R, 19G, and 19B. Hence, each of the light-emitting components 19R, 19G, and 19B does not cover any slit 141s. At least a portion of the opaque layer 180 is located in the slits 141s. For example, the opaque layer 180 can fill the slits 141s, as shown in FIG. 2A.

When the light-emitting component (e.g., light-emitting component 19G) emits the light L22 downwards, the first inner wiring layer 130 located directly below the light-emitting components 19G will reflect the light L21 to the outer wiring layer 140 (e.g., electrode layers 141c), so that the light L21 will repeatedly reflect between the first inner wiring layer 130 and the outer wiring layer 140. The slits 141s can increase the chance of the light L21 entering the opaque layer 180, so that the opaque layer 180 can absorb more light L21 undergoing the reflection inside the outer insulating layer 152, thereby helping to reduce or to prevent light leakage, and thus improving the image quality.

It is worth mentioning that in another embodiment, the electrode layers 141c and 141a may not have any slit 141s, while the opaque layer 180 can effectively absorb the light undergoing the reflection inside the outer insulating layer 152, thereby achieving the efficacy of reducing or preventing light leakage under the condition that the ratio of the protruding length PL2 to the perpendicular distance 152t is greater than or equal to 2. In addition, these slits 141s of the electrode layers 141c also can effectively absorb the light undergoing the reflection inside the outer insulating layer 152. Hence, in another embodiment, even if the ratio of the protruding length PL2 to the perpendicular distance 152t is not greater than or equal to 2, these slits 141s also can achieve the efficacy of reducing or preventing light leakage.

The light-transmitting composite substrate 200 includes a transparent plate 290, two inner insulating layers 252 and 253, a second inner wiring layer 220, and a third inner wiring layer 210. The transparent plate 290 can be a glass plate or a sapphire substrate, while these inner insulating layers 252 and 253, the second inner wiring layer 220, and the third inner wiring layer 210 are in a stack and disposed on the transparent plate 290. The inner insulating layers 252 and 253 are located between the transparent plate 290 and the second inner wiring layer 220, and the inner insulating layer 151 covers the second inner wiring layer 220 and the inner insulating layer 252. The third inner wiring layer 210 is sandwiched between the inner insulating layers 252 and 253, and located between the second inner wiring layer 220 and the transparent plate 290.

The light-transmitting composite substrate 200 further includes a patterned semiconductor layer 260 disposed on the transparent plate 290, in which the inner insulating layer 253 covers the patterned semiconductor layer 260 and the surface (e.g., upper surface) of the transparent plate 290. The light-transmitting composite substrate 200 further includes a plurality of conductive pillars 254, in which each of the conductive pillars 254 passes through the inner insulating layers 252 and 253, and is connected to the second inner wiring layer 220 and the patterned semiconductor layer 260, so that the second inner wiring layer 220 and the patterned semiconductor layer 260 are electrically connected to each other.

The patterned semiconductor layer 260, the second inner wiring layer 220, the third inner wiring layer 210, the conductive pillars 254, and the inner insulating layer 252 and 253 can form a plurality of thin-film transistors (TFTs) TR2. Specifically, at least a portion of the third inner wiring layer 210 overlaps the patterned semiconductor layer 260, while the inner insulating layer 253 is sandwiched between the third inner wiring layer 210 and the patterned semiconductor layer 260, thereby forming a capacitance. As a result, the portion of the third inner wiring layer 210 which overlaps the patterned semiconductor layer 260 can be used as a gate and located between two conductive pillars 254.

The second inner wiring layer 220 includes a plurality of sources S2 and a plurality of drains C2, where the conductive pillars 254 are electrically connected to the sources S2 and the drains C2 respectively, so that the sources S2 and the drains C2 can be electrically connected to the patterned semiconductor layer 260 via the conductive pillars 254, but cannot be electrically connected to the third inner wiring layer 210 (including gates) directly. Accordingly, the patterned semiconductor layer 260, the second inner wiring layer 220, the third inner wiring layer 210, the conductive pillars 254, and the inner insulating layers 252 and 253 can form a plurality of Field-Effect Transistors (FETs), i.e., TFTs TR2.

As a result, the light-transmitting composite substrate 200 can have a wiring structure and a plurality of active components (e.g., TFTs TR2). In addition, the light-transmitting composite substrate 200 can be electrically connected to the first inner wiring layer 130 via a plurality of contact windows (not shown) disposed in the inner insulating layer 151, so that the TFTs TR2 in the light-transmitting composite substrate 200 can be electrically connected to the light-emitting components 19R, 19G, and 19B. Accordingly, the TFTs TR2 can control the light-emitting components 19R, 19G, and 19B.

FIG. 2A is a cross-sectional view of FIG. 1B along a line 2-2, in which the FIG. 2B is an enlarged view of a portion of the electrode layer 141c in FIG. 2A. Referring to FIG. 2A and FIG. 2B, in the present embodiment, at least one of the electrode layers (e.g., electrode layers 141a or 141c) of the outer wiring layer 140 includes a blackened conductive layer A14 and a metal layer M14. The blackened conductive layer A14 is disposed on the plane 152s of the outer insulating layer 152, while the metal layer M14 is disposed on the blackened conductive layer A14. Hence, the blackened conductive layer A14 is located between the metal layer M14 and the outer insulating layer 152.

The metal layer M14 can be a molybdenum layer, while the blackened conductive layer A14 can be made of conductive oxide, such as NbSiCOₓ, CrOₓ, MoOₓ, or MoOₓTa. The thickness of the metal layer M14 can range between 500 Å (Angstrom) and 3500 Å, such as between 500 Å and 3000 Å, or between 500 Å and 1500 Å, while the thickness of the blackened conductive layer A14 can range between 450 Å and 600 Å. Hence, the thickness of at least one of the electrode layers 141c and 141a (or the whole outer wiring layer 140) can range between 950 Å and 3600 Å.

The total thickness, the optical density, and the average reflectivity of at least one of the electrode layers 141a and 141c are listed in the following TABLE 1.

TABLE 1

| | Total Thickness of Electrode | | |
|---|---|---|---|
| | Layer (Thickness of | Optical | |
| | Blackened Conductive Layer | Density | Average |
| | A14 Plus Metal Layer M14) | (OD) | Reflectivity |
| Sample A | 1000 Å | 2.3 | 7.1% |
| Sample B | 2000 Å | 5.4 | 8.5% |
| Sample C | 3500 Å | 7.2 | 9.2% |

Referring to Table 1, at least one of the electrode layers 141c and 141a has relatively low average reflectivity and the optical density that is greater than or equal to 1, so that the electrode layers 141a or 141c including the blackened conductive layer A14 can absorb most of visible light and especially absorb the light (e.g., light L21 and L22) undergoing the reflection inside the outer insulating layer 152, so as to reduce or prevent light leakage, thereby improving image quality. In addition, in another embodiment, the blackened conductive layer A14 also may have a multilayer structure and a function of anti-reflection.

For example, the blackened conductive layer A14 may substantially be a Fabry-Pérot interferometer, so that the blackened conductive layer A14 has the function of anti-reflection. Accordingly, the outer wiring layer 140 can reduce the reflection of light (e.g., the light L23 shown in FIG. 2A), thereby improving the image quality of the transparent display 100.

It is worth mentioning that since the blackened conductive layer A14 can effectively absorb the light undergoing the reflection inside the outer insulating layer 152, the blackened conductive layer A14 also can achieve the efficacy of reducing or preventing light leakage, thereby improving the image quality of the transparent display 100, even if the electrode layers 141c and 141a do not have any slit 141s, and the ratio of the protruding length PL2 to the perpendicular distance 152t is not greater than or equal to 2.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A transparent display, comprising:
a light-transmitting composite substrate;
an inner insulating layer, disposed on the light-transmitting composite substrate;
an outer insulating layer, disposed on the inner insulating layer and having a plane;
an opaque layer, disposed on the plane and comprising:
a plurality of first opaque bars, extending in a first direction;
a plurality of second opaque bars, extending in a second direction, wherein the opaque layer defines a plurality of transparent areas on the plane, and the first opaque bars and the second opaque bars are located around the transparent areas;
a first inner wiring layer, disposed on the inner insulating layer and covered by the outer insulating layer;
a plurality of electrode layers, disposed on the plane and having a plurality of side edges respectively, wherein each of the side edges is adjacent to one of the transparent areas,
wherein the opaque layer covers each of the side edges and protrudes from each of the side edges by a protruding length in the first direction,
wherein there is a perpendicular distance formed between the electrode layers and the inner wiring layer, and a ratio of the protrusion length to the perpendicular distance is greater than or equal to 2; and
a plurality of light-emitting components, disposed on the electrode layers.

2. The transparent display of claim 1, further comprising:
a molding layer, disposed on the plane and covering the light-emitting components, wherein the molding layer has a thickness,
wherein the opaque layer has:
a plurality of inner edges on the electrode layers; and
a plurality of outer edges adjacent to the transparent areas,
wherein among adjacent ones of the inner edges and the outer edges, the opaque layer has an extension length in the first direction from one of the inner edges to one of the outer edges, and a ratio of the extension length to the thickness is greater than or equal to 5.

3. The transparent display of claim 1, wherein the electrode layers comprise:
a plurality of cathodes, having a plurality of slits extending in the second direction, wherein at least a portion of the opaque layer is located in the slits; and
a plurality of anodes, wherein each of the anodes is disposed opposite to one of the cathodes and is disposed on one of the anodes and one of the cathodes, wherein the slits do not overlap the light-emitting components.

4. The transparent display of claim 3, wherein the opaque layer fills the slits.

5. The transparent display of claim 4, wherein at least one of the electrode layers comprises:
a blackened conductive layer, disposed on the plane; and
a metal layer, disposed on the blackened conductive layer.

6. The transparent display of claim 1, wherein at least one of the electrode layers comprises:
a blackened conductive layer, disposed on the plane; and
a metal layer, disposed on the blackened conductive layer.

7. The transparent display of claim 6, wherein the blackened conductive layer is made of conductive oxide.

8. The transparent display of claim 1, wherein the opaque layer is in the shape of a mesh, and the first direction is perpendicular to the second direction.

9. A transparent display, comprising:
a light-transmitting composite substrate;
an inner insulating layer, disposed on the light-transmitting composite substrate;
an outer insulating layer, disposed on the inner insulating layer and having a plane;
an opaque layer, disposed on the plane and comprising:
a plurality of first opaque bars, extending in a first direction;
a plurality of second opaque bars, extending in a second direction, wherein the opaque layer defines a plurality of transparent areas on the plane, and the first opaque bars and the second opaque bars are located around the transparent areas;
a plurality of electrode layers, disposed on the plane and having a plurality of side edges respectively, wherein each of the side edges is adjacent to one of the transparent areas,
wherein the opaque layer covers each of the side edges, and the electrode layers comprises:
a plurality of cathodes, having a plurality of slits extending in the second direction, wherein at least a portion of the opaque layer is located in the slits;
a plurality of anodes, wherein each of the anodes is disposed opposite to one of the cathodes;
a first inner wiring layer, disposed on the inner insulating layer and covered by the outer insulating layer; and
a plurality of light-emitting components, disposed on the electrode layers, wherein each of the light-emitting components is disposed on one of the anodes and one of the cathodes.

10. The transparent display of claim 9, wherein the opaque layer fills the slits.

11. The transparent display of claim 9, further comprising:
a molding layer, disposed on the plane and covering the light-emitting components, wherein the molding layer has a thickness,
wherein the opaque layer has:
a plurality of inner edges on the electrode layers; and
a plurality of outer edges adjacent to the transparent areas,
wherein among adjacent ones of the inner edges and the outer edges, the opaque layer has an extension length in the first direction from one of the inner edges to one of the outer edges, and a ratio of the extension length to the thickness is greater than or equal to 5.

12. The transparent display of claim 11, wherein the opaque layer fills the slits.

13. A transparent display, comprising:
a light-transmitting composite substrate;
an inner insulating layer, disposed on the light-transmitting composite substrate;
an outer insulating layer, disposed on the inner insulating layer and having a plane;
an opaque layer, disposed on the plane and comprising:
a plurality of first opaque bars, extending in a first direction;
a plurality of second opaque bars, extending in a second direction, wherein the opaque layer defines a plurality of transparent areas on the plane, and the first opaque bars and the second opaque bars are located around the transparent areas;
a plurality of electrode layers, disposed on the plane and having a plurality of side edges respectively, wherein each of the side edges is adjacent to one of the transparent areas,
wherein the opaque layer covers each of the side edges, and at least one of the electrode layers:
a blackened conductive layer, disposed on the plane;
a metal layer, disposed on the blackened conductive layer;
a first inner wiring layer, disposed on the inner insulating layer and covered by the outer insulating layer; and
a plurality of light-emitting components, disposed on the electrode layers.

14. The transparent display of claim 13, wherein the blackened conductive layer is made of conductive oxide.

15. The transparent display of claim 13, wherein the metal layer is a molybdenum layer.
